(19) United States
(12) Patent Application Publication
(10) Pub. No.: US 2019/0017798 A1
(43) Pub. Date: Jan. 17, 2019

(54) Position Indicator and Calibration Method Thereof

(71) Applicant: Sunrex Technology Corp., Taichung City (TW)

(72) Inventor: Shun-Pin Lin, New Taipei City (TW)

(21) Appl. No.: 15/833,026

(22) Filed: Dec. 6, 2017

(30) Foreign Application Priority Data
Jul. 13, 2017 (TW) 106210296

(51) Int. Cl. G01B 7/00; H03K 5/156; G01D 5/14; G06F 3/01; H02J 50/80

(52) U.S. Cl. CPC G01B 7/003; H03K 5/1565; H02J 50/80; G06F 3/01; G01D 5/14

(57) ABSTRACT

A position indicator includes an output generator and a controller. The output generator generates, based on a control signal, a drive voltage that has a magnitude related to a duty cycle of the control signal, and generates, based on a control input, an output signal that is switchable between the drive voltage and a ground voltage. The controller stores a number (N) of voltage setting values, and obtains a number (N) of target duty cycle values that respectively correspond to the voltage setting values, where N≥1. The controller generates the control signal based at least on the target duty cycle values, and generates the control input.

### CROSS-REFERENCE TO RELATED APPLICATION

This application claims priority of Taiwanese Patent Application No. 106210296, filed on Jul. 13, 2017.

### FIELD

The disclosure relates to position indication, and more particularly to a position indicator and a calibration method thereof.

### BACKGROUND

A stylus can be used with an electronic device that requires data input, such as a mobile phone, a tablet computer, a laptop computer or the like. In view of distinct requirements on the intensity of the input signals for electronic devices manufactured by different electronic device manufacturers, a position indicator manufacturer has to change the intensity of the output signals of the position indicators every time the position indicators are to be used with a different type of electronic devices so as to adapt the position indicators to fulfill the requirements of that type of electronic devices. This change is conventionally made by modifying the hardware of the position indicators, resulting in relatively high costs.

### SUMMARY

Therefore, an object of the disclosure is to provide a position indicator that can alleviate the drawback of the prior art, and a calibration method thereof.

According to an aspect of the disclosure, the position indicator includes an output generator and a controller. The output generator receives a control signal and a control input; generates, based on the control signal, a drive voltage that has a magnitude related to a duty cycle of the control signal; and generates, based on the control input, an output signal that is switchable between the drive voltage and a ground voltage. The controller is coupled to the output generator, stores a number (N) of voltage setting values, and obtains a number (N) of target duty cycle values that respectively correspond to the voltage setting values, where N≥1. The controller generates, based at least on the target duty cycle values, the control signal for receipt by the output generator, and generates the control input for receipt by the output generator.

In one embodiment, the output generator further generates a feedback signal that indicates the drive voltage, and the controller receives the feedback signal from the output generator, and obtains each of the target duty cycle values based on the feedback signal and the respective one of the voltage setting values.

According to another aspect of the disclosure, the calibration method is to be performed by a controller of a position indicator according to said one embodiment. The calibration method includes steps of: (A) adjusting, based on the feedback signal, a switching frequency of the control signal to a value that makes the magnitude of the drive voltage maximum and that serves as a target frequency value; and (B) for each of the voltage setting values, adjusting, based on the feedback signal and the voltage setting value, the duty cycle of the control signal to a value that makes the magnitude of the drive voltage equal to the voltage setting value and that serves as the respective one of the target duty cycle values.

### BRIEF DESCRIPTION OF THE DRAWINGS

Other features and advantages of the disclosure will become apparent in the following detailed description of the embodiment with reference to the accompanying drawings, of which:

FIG. 1 is a circuit block diagram illustrating an embodiment of a position indicator according to the disclosure; and

FIGS. 2 to 4 are flow charts illustrating a calibration method performed by the embodiment.

### DETAILED DESCRIPTION

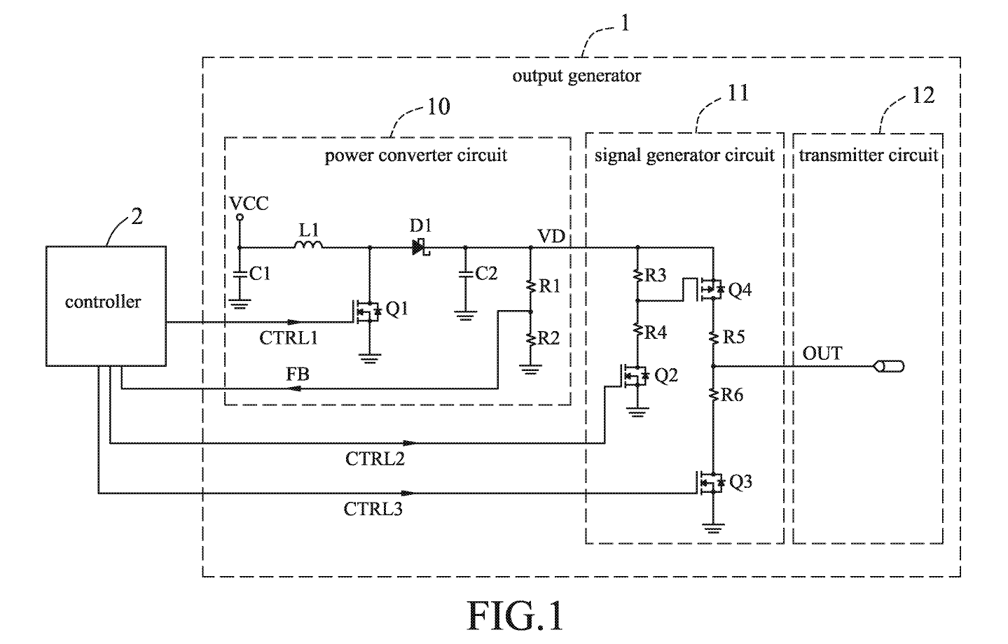

Referring to FIG. 1, an embodiment of a position indicator according to the disclosure (e.g., a stylus) is operatively associated with a position detector (e.g., a touch screen) (not shown) of an electronic device (not shown), and includes an output generator 1 and a controller 2.

The output generator 1 receives a first control signal (CTRL1) that is pulse width modulated; generates, based on the first control signal (CTRL1), a drive voltage (VD) that has a magnitude related to a duty cycle of the first control signal (CTRL1); and generates a feedback signal (FB) that indicates the drive voltage (VD). The output generator 1 further receives a control input, and generates, based on the control input, an output signal (OUT) that is switchable between the drive voltage (VD) and a ground voltage and that is to be received by the position detector.

In this embodiment, the output generator 1 includes a power converter circuit 10, a signal generator circuit 11 and a transmitter circuit 12.

The power converter circuit 10 is used to receive a direct current (DC) supply voltage (VCC), further receives the first control signal (CTRL1), performs, based on the first control signal (CTRL1), DC-to-DC conversion on the supply voltage (VCC) to generate the drive voltage (VD), and divides the drive voltage (VD) to generate the feedback signal (FB). In this embodiment, the power converter circuit 10 includes an inductor (L1), two capacitors (C1, C2), a switch (Q1), a diode (D1) and two resistors (R1, R2). The inductor (L1) has a first terminal that is used to receive the supply voltage (VCC), and a second terminal. The capacitor (C1) is coupled between the first terminal of the inductor (L1) and ground. The switch (Q1) (e.g., an N-channel metal oxide semiconductor field effect transistor (nMOSFET)) has a first terminal (e.g., a drain terminal) that is coupled to the second terminal of the inductor (L1), a second terminal (e.g., a source terminal) that is grounded, and a control terminal (e.g., a gate terminal) that receives the first control signal (CTRL1). The diode (D1) (e.g., a Schottky diode) has an anode that is coupled to the second terminal of the inductor (L1), and a cathode. The capacitor (C2) is coupled between the cathode of the diode (D1) and ground, and a voltage thereacross serves as the drive voltage (VD). The resistor (R1) a first terminal that is coupled to the cathode of the diode (D1), and a second terminal. The resistor (R2) is coupled between the second terminal of the resistor (R1) and ground, and a voltage thereacross serves as the feedback signal (FB). Therefore, the magnitude of the drive voltage (VD) is positively correlated to the duty cycle of the first control signal (CTRL1).

The signal generator circuit 11 is coupled to the cathode of the diode (D1) for receiving the drive voltage (VD) therefrom, further receives the control input, and outputs one of the drive voltage (VD) and the ground voltage based on the control input to generate the output signal (OUT). In this embodiment, the control input includes a second control signal (CTRL2) and a third control signal (CTRL3), each of which is switchable between a logic high level and a logic low level, and which are complementary to each other. In addition, the signal generator circuit 11 includes four resistors (R3-R6) and three switches (Q2-Q4). The resistor (R3) has a first terminal that is coupled to the cathode of the diode (D1) for receiving the drive voltage (VD) therefrom, and a second terminal. The resistor (R4) has a first terminal that is coupled to the second terminal of the resistor (R3), and a second terminal. The switch (Q2) (e.g., an nMOSFET) has a first terminal (e.g., a drain terminal) that is coupled to the second terminal of the resistor (R4), a second terminal (e.g., a source terminal) that is grounded, and a control terminal (e.g., a gate terminal) that receives the second control signal (CTRL2). The switch (Q4) (e.g., a P-channel metal oxide semiconductor field effect transistor (pMOSFET)) has a first terminal (e.g., a source terminal) that is coupled to the first terminal of the resistor (R3), a second terminal (e.g., a drain terminal), and a control terminal (e.g., a gate terminal) that is coupled to the second terminal of the resistor (R3). The resistor (R5) has a first terminal that is coupled to the second terminal of the switch (Q4), and a second terminal. The resistor (R6) has a first terminal that is coupled to the second terminal of the resistor (R5), and a second terminal. The switch (Q3) (e.g., an nMOSFET) has a first terminal (e.g., a drain terminal) that is coupled to the second terminal of the resistor (R6), a second terminal (e.g., a source terminal) that is grounded, and a control terminal (e.g., a gate terminal) that receives the third control signal (CTRL3). The output signal (OUT) is provided at the second terminal of the resistor (R5). When the second control signal (CTRL2) is at the logic high level while the third control signal (CTRL3) is at the logic low level, the switches (Q2, Q4) both conduct while the switch (Q3) does not conduct, and the drive voltage (VD) is outputted through the conducting switch (Q4) to serve as the output signal (OUT). When the second control signal (CTRL2) is at the logic low level while the third control signal (CTRL3) is at the logic high level, neither of the switches (Q2, Q4) conducts while the switch (Q3) conducts, and the ground voltage is outputted through the conducting switch (Q3) to serve as the output signal (OUT).

The transmitter circuit 12 is coupled to the second terminal of the resistor (R5) for receiving the output signal (OUT) therefrom, transmits the output signal (OUT) when the output signal (OUT) switches between the drive voltage (VD) and the ground voltage at a frequency within a predetermined frequency band of non-zero frequencies, and does not transmit the output signal (OUT) otherwise. In this embodiment, the transmitter circuit 12 is made of a metallic conductor, or an impedance material that is resilient or wear-resistant and that has a high impedance.

The controller 2 is coupled to the respective control terminals of the switches (Q1-Q3), is coupled further to the second terminal of the resistor (R1) for receiving the feedback signal (FB) therefrom, and stores a number (N) of voltage setting values, where N≥1. In this embodiment, the position indicator is operable in one of three operating modes that include a calibration mode, a normal mode and a power saving mode, and the controller 2 generates the first, second and third control signals (CTRL1, CTRL2, CTRL3) based on the operating mode the position indicator operates in. The voltage setting values respectively correspond to a number (N) of actions to be performed by the position indicator in the normal mode, and can be changed depending on requirements from one of electronic device manufacturers. In one example, N=3, the voltage setting values are respectively 15V, 10V and 5V, and the actions to be performed in the normal mode includes: (a) assisting the position detector in determining a position of the position indicator relative to the position detector (which corresponds to the voltage setting value of 15V); (b) transmitting data “0” to the position detector (which corresponds to the voltage setting value of 10V); and (c) transmitting data “1” to the position detector (which corresponds to the voltage setting value of 5V).

In the calibration mode, the controller 2 obtains a target frequency value and a number (N) of target duty cycle values that respectively correspond to the voltage setting values. In the normal mode, the controller 2 generates, based on the target frequency value, on the target duty cycle values and on the actions to be performed by the position indicator, the first control signal (CTRL1) for the control terminal of the switch (Q1), and generates the second and third control signals (CTRL2, CTRL3) respectively for the respective control terminals of the switches (Q2, Q3).

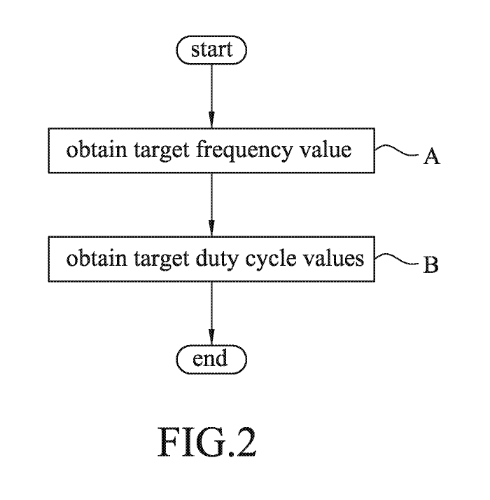

Referring to FIGS. 1 to 4, when the position indicator of this embodiment operates in the calibration mode, the controller 2 sets the second control signal (CTRL2) to the logic low level, and sets the third control signal (CTRL3) to the logic high level, so the output signal (OUT) is at the ground voltage. In addition, the controller 2 performs a calibration method that includes the following steps (A, B) as shown in FIG. 2 to obtain the target frequency value and the target duty cycle values.

In step (A), the controller 2 adjusts, based on the feedback signal (FB), a switching frequency of the first control signal (CTRL1) to a value that makes the magnitude of the drive voltage (VD) maximum and that serves as the target frequency value, and stores the target frequency value. It should be noted that the magnitude of the drive voltage (VD) reaches its maximum when the switching frequency of the first control signal (CTRL1) is substantially equal to a resonant frequency of the inductor (L1) and the capacitor (C2).

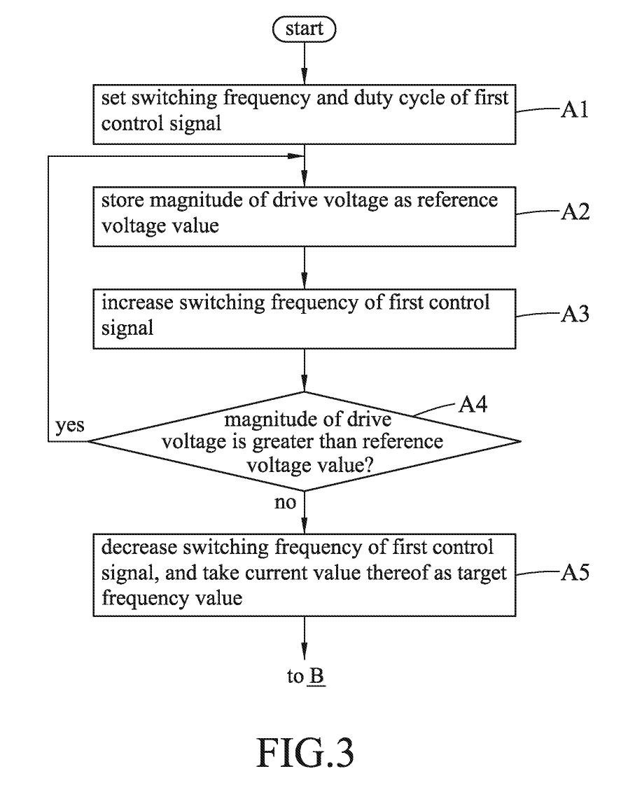

In this embodiment, step (A) includes the following sub-steps (A1-A5) as shown in FIG. 3.

In sub-step (A1), the controller 2 sets the switching frequency of the first control signal (CTRL1) to a relatively low predetermined frequency value, and sets the duty cycle of the first control signal (CTRL1) to a predetermined duty cycle value, 50%). Therefore, the drive voltage (VD) and the feedback signal (FB) both change in response to the setting of the switching frequency and the duty cycle of the first control signal (CTRL1).

In sub-step (A2), the controller 2 stores, based on the feedback signal (FB), the magnitude of the drive voltage (VD) as a reference voltage value in a digital form.

In sub-step (A3), the controller 2 increases the switching frequency of the first control signal (CTRL1) by a predetermined frequency interval which may be a fixed value or may vary according to the current switching frequency. Therefore, the drive voltage (VD) and the feedback signal (FB) both change in response to the increase of the switching frequency of the first control signal (CTRL1).

In sub-step (A4), the controller 2 determines, based on the feedback signal (FB) and the reference voltage value, whether the magnitude of the drive voltage (VD) is greater than the reference voltage value. If affirmative, the flow goes back to sub-step (A2). Otherwise, the flow proceeds to sub-step (A5). In this embodiment, the controller 2 includes an analog-to-digital converter (not shown) to perform analog-to-digital conversion on the feedback signal (FB), and makes the determination based on digital representation of the feedback signal (FB).

In sub-step (A5), the controller 2 decreases the switching frequency of the first control signal (CTRL1) by the predetermined frequency interval to a decreased value, takes the decreased value as the target frequency value, and stores the target frequency value. Therefore, the drive voltage (VD) and the feedback signal (FB) both change in response to the decrease of the switching frequency of the first control signal (CTRL1).

In step (B), for each voltage setting value, the controller 2 adjusts, based on the feedback signal (FB) and the voltage setting value, the duty cycle of the first control signal (CTRL1) to a value that makes the magnitude of the drive voltage (VD) equal to the voltage setting value and that serves as the respective target duty cycle value, and stores the respective target duty cycle value. In this embodiment, the duty cycle of the first control signal (CTRL1) is not greater than an upper limit of 90%.

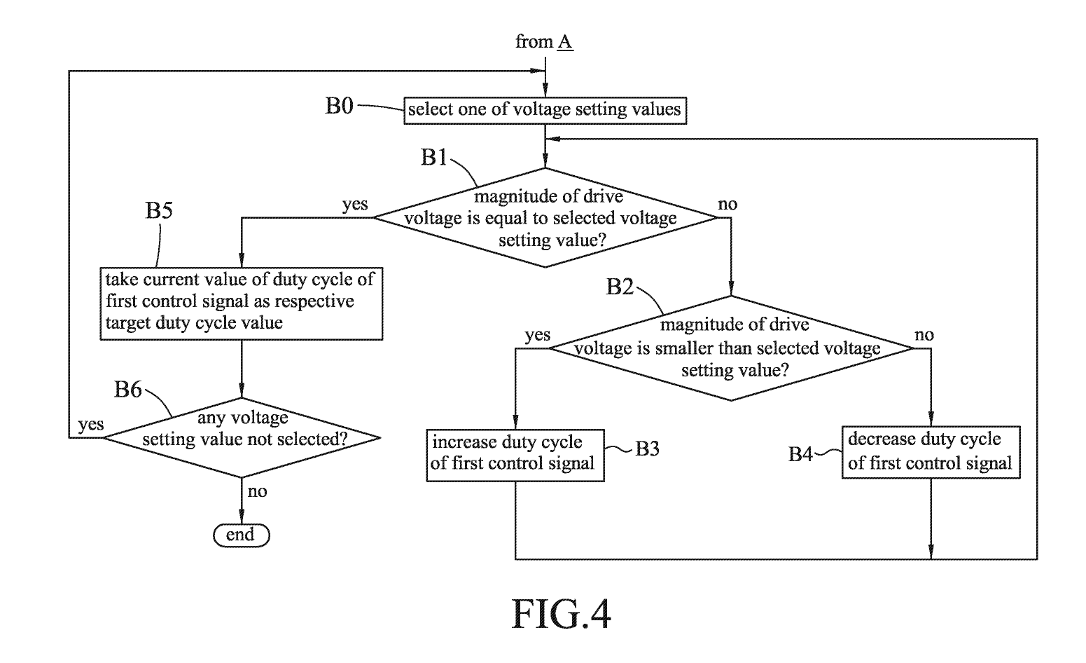

In this embodiment, step (B) includes the following sub-steps (B0-B6) as shown in FIG. 4.

In sub-step (B0) the controller 2 selects one of the voltage setting values.

In sub-step (B1), the controller 2 determines, based on the feedback signal (FB) and the selected voltage setting value, whether the magnitude of the drive voltage (VD) is equal to the selected voltage setting value. If affirmative, the flow proceeds to sub-step (B5). Otherwise, the flow proceeds to sub-step (B2).

In sub-step (B2), the controller 2 determines, based on the feedback signal (FB) and the selected voltage setting value, whether the magnitude of the drive voltage (VD) is smaller than the selected voltage setting value. If affirmative, the flow proceeds to sub-step (B3). Otherwise, the flow proceeds to sub-step (B4).

In sub-step (B3), the controller 2 increases the duty cycle of the first control signal (CTRL1). Therefore, the drive voltage (VD) and the feedback signal (FB) both increase in response to the increase of the duty cycle of the first control signal (CTRL1).

In sub-step (B4), the controller 2 decreases the duty cycle of the first control signal (CTRL1). Therefore, the drive voltage (VD) and the feedback signal (FB) both decrease in response to the decrease of the duty cycle of the first control signal (CTRL1).

After each of sub-steps (B3, B4), the flow goes back to sub-step (B1).

In sub-step (B5), the controller 2 takes a value of the duty cycle corresponding to the feedback signal (FB) as the target duty cycle value for the selected voltage setting value, and stores the target duty cycle value.

In sub-step (B6), the controller 2 determines whether any one of the voltage setting values has not been selected. If affirmative, the flow goes back to sub-step (B0) for another voltage setting value. Otherwise, the flow ends.

It should be noted that each of sub-steps (A2, A4, B1, B2) is executed after the drive voltage (VD) and the feedback signal (FB) both become stable.

Referring to FIG. 1, when the position indicator of this embodiment operates in the normal mode, the controller 2 selects one of the stored target duty cycle values that corresponds to the action to be performed by the position indicator of this embodiment, sets the duty cycle of the first control signal (CTRL1) to the selected target duty cycle value, and sets the switching frequency of the first control signal (CTRL1) to the stored target frequency value, so the drive voltage (VD) becomes substantially equal to one of the voltage setting values that corresponds to the action to be performed by the position indicator of this embodiment. In addition, the controller 2 generates the second and third control signals (CTRL2, CTRL3) each switching between the logic high level and the logic low level at a predetermined frequency within the predetermined frequency band, so the output signal (OUT) switches between the drive voltage (VD) and the ground voltage at the predetermined frequency.

When the position indicator of this embodiment operates in the power saving mode, the controller 2 sets the duty cycle of the first control signal (CTRL1) to zero, so the magnitude of the drive voltage (VD) becomes zero. In addition, the controller 2 sets the second control signal (CTRL2) to the logic low level, and sets the third control signal (CTRL3) to the logic high level, so the output signal (OUT) is at the ground voltage.

In view of the above, in this embodiment, by virtue of the controller 2 that stores the voltage setting values, change of the voltage setting values can be made by modifying firmware, instead of hardware, of the controller 2, reducing costs incurred for adapting the position indicator to different requirements. In addition, by virtue of the controller 2 that sets the duty cycle of the first control signal (CTRL1) to zero and that sets the second and third control signals (CTRL2, CTRL3) respectively to the logic low level and the logic high level when the position indicator operates in the power saving mode, power consumption of the position indicator can be reduced.

In the description above, for the purposes of explanation, numerous specific details have been set forth in order to provide a thorough understanding of the embodiment. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects.

While the disclosure has been described in connection with what is considered the exemplary embodiment, it is understood that the disclosure is not limited to the disclosed embodiment but is intended to cover various arrangements included within the spirit and scope of the broadest interpretation so as to encompass all such modifications and equivalent arrangements.

What is claimed is:

1. A position indicator comprising:
an output generator receiving a first control signal and a control input; generating, based on the first control signal, a drive voltage that has a magnitude related to a duty cycle of the first control signal; and generating, based on the control input, an output signal that is switchable between the drive voltage and a ground voltage; and
a controller coupled to said output generator, storing a number (N) of voltage setting values, and obtaining a number (N) of target duty cycle values that respectively correspond to the voltage setting values, where N≥1, said controller generating, based at least on the target duty cycle values, the first control signal for receipt by said output generator, and generating the control input for receipt by said output generator.

2. The position indicator of claim 1, wherein:
said output generator further generates a feedback signal that indicates the drive voltage; and
said controller receives the feedback signal from said output generator, and obtains each of the target duty cycle values based on the feedback signal and the respective one of the voltage setting values.

3. The position indicator of claim 2, wherein said output generator includes:
a power converter circuit coupled to said controller, used to receive a supply voltage, further receiving the first control signal from said controller, converting the supply voltage into the drive voltage based on the first control signal, and generating the feedback signal for receipt by said controller;
a signal generator circuit coupled to said controller and said power converter circuit for receiving the control input and the drive voltage respectively therefrom, and outputting one of the drive voltage and the ground voltage based on the control input to generate the output signal; and
a transmitter circuit coupled to said signal generator circuit for receiving the output signal therefrom, and transmitting the output signal.

4. The position indicator of claim 3, wherein said power converter circuit includes:
an inductor having a first terminal that is used to receive the supply voltage, and a second terminal;
a switch having a first terminal that is coupled to said second terminal of said inductor, a second terminal that is grounded, and a control terminal that is coupled to said controller for receiving the first control signal therefrom;
a diode having an anode that is coupled to said second terminal of said inductor, and a cathode;
a capacitor coupled between said cathode of said diode and ground, a voltage across said capacitor serving as the drive voltage.

5. The position indicator of claim 4, wherein said power converter circuit further includes:
a first resistor having a first terminal that is coupled to said cathode of said diode, and a second terminal; and
a second resistor coupled between said second terminal of said first resistor and ground, a voltage across said second resistor serving as the feedback signal.

6. The position indicator of claim 3, wherein the control input includes a second control signal and a third control signal that are complementary to each other, and said signal generator circuit includes:
a first resistor having a first terminal that is coupled to said power converter circuit for receiving the drive voltage therefrom, and a second terminal;
a second resistor having a first terminal that is coupled to said second terminal of said first resistor, and a second terminal;
a first switch having a first terminal that is coupled to said second terminal of said second resistor, a second terminal that is grounded, and a control terminal that is coupled to said controller for receiving the second control signal therefrom;
a second switch having a first terminal that is coupled to said first terminal of said first resistor, a second terminal, and a control terminal that is coupled to said second terminal of said first resistor;
a third resistor having a first terminal that is coupled to said second terminal of said second switch, and a second terminal that is coupled to said transmitter circuit and that provides the output signal for receipt by said transmitter circuit;
a fourth resistor having a first terminal that is coupled to said second terminal of said third resistor, and a second terminal; and
a third switch having a first terminal that is coupled to said second terminal of said fourth resistor, a second terminal that is grounded, and a control terminal that is coupled to said con roller for receiving the third control signal therefrom.

7. The position indicator of claim 3, wherein said transmitter circuit is made of an impedance material.

8. The position indicator of claim 2, being operable in a calibration mode, wherein, when said position indicator operates in the calibration mode, for each of the voltage setting values, said controller adjusts, based on the feedback signal and the voltage setting value, the duty cycle of the first control signal to a value that makes the magnitude of the drive voltage equal to the voltage setting value and that serves as the respective one of the target duty cycle values.

9. The position indicator of claim 8, wherein:
when said position indicator operates in the calibration mode, said controller further adjusts, based on the feedback signal, a switching frequency of the first control signal to a value that makes the magnitude of the drive voltage maximum and that serves as a target frequency value; and
said controller generates the first control signal based further on the target frequency value.

10. The position indicator of claim 9, wherein, when said position indicator operates in the calibration mode, said controller generates the control input in such a way that the output signal is at the ground voltage.

11. The position indicator of claim 9, wherein, when said position indicator operates in the calibration mode, said controller further stores the target frequency value and the target duty cycle values.

12. The position indicator of claim 11, being operable further in a normal mode, wherein, when said position indicator operates in the normal mode, said controller sets the switching frequency of the first control signal to the target frequency value stored therein, sets the duty cycle of the first control signal to one of the target duty cycle values stored therein, and generates the control input in such a way that the output signal switches between the drive voltage and the ground voltage at a predetermined frequency.

13. The position indicator of claim 12, being operable further a power saving mode, wherein, when said position indicator operates in the power saving mode, said controller sets the duty cycle of the first control signal to zero, and generates the control input in such a way that the output signal is at the ground voltage.

14. A calibration method to be performed by a controller of a position indicator according to claim 2, said calibration method comprising steps of:
(A) adjusting, based on the feedback signal, a switching frequency of the first control signal to a value that makes the magnitude of the drive voltage maximum and that serves as a target frequency value; and
(B) for each of the voltage setting values, adjusting, based on the feedback signal and the voltage setting value, the duty cycle of the first control signal to a value that makes the magnitude of the drive voltage equal to the voltage setting value and that serves as the respective one of the target duty cycle values.

15. The calibration method of claim 14, wherein, step (A) further includes: storing the target frequency value; and step (B) further includes: storing the respective one of the target duty cycle values.

16. The calibration method of claim 14, wherein step (A) includes sub-steps of:
(A1) setting the switching frequency of the first control signal to a predetermined frequency value;
(A2) storing, based on the feedback signal, the magnitude of the drive voltage as a reference voltage value;
(A3) increasing the switching frequency o the first control signal;
(A4) determining, based on the feedback signal and the reference voltage value, whether the magnitude of the drive voltage is greater than the reference voltage value; and
(A5) when it is determined in sub-step (A4) that the magnitude of the drive voltage is not greater than the reference voltage value, decreasing the switching frequency of the first control signal to a decreased value, and taking the decreased value as the target frequency value;
when it is determined in sub-step (A4) that the magnitude of the drive voltage is greater than the reference voltage value, sub-steps (A2) and (A3) being repeated.

17. The calibration method of claim 14, wherein step (B) includes sub-steps of:
(B1) determining, based on the feedback signal and one of the voltage setting values, whether the magnitude of the drive voltage is equal to said one of the voltage setting values;
(B2) when it is determined in sub-step that the magnitude of the drive voltage is not equal to said one of the voltage setting values, determining, based on the feedback signal and said one of the voltage setting values, whether the magnitude of the drive voltage is smaller than the voltage setting value;
(B3) when it is determined in sub-step (B2) that the magnitude of the drive voltage is smaller than said one of the voltage setting values, increasing the duty cycle of the first control signal;
(B4) when it is determined in sub-step (B2) that the magnitude of the drive voltage is not smaller than said one of the voltage setting values, decreasing the duty cycle of the first control signal; and
(B5) when it is determined in sub-step (B1) that the magnitude of the drive voltage is equal to said one of the voltage setting values, taking a value of the duty cycle of the first control signal that corresponds to the drive voltage to be one of the target duty cycle values that corresponds to said one of the voltage setting values.
